(19) United States
(12) Patent Application Publication
(10) Pub. No.: US 2011/0127073 A1
(43) Pub. Date: Jun. 2, 2011

(54) PRINTED CIRCUIT BOARD AND MANUFACTURING METHOD THEREOF

(75) Inventors: Joung-Gul Ryu, Seoul (KR); Sang-Youp Lee, Seoul (KR); Dong-Sun Kim, Suwon-si (KR); Jae-Hoon Choi, Yongin-si (KR); In-Ho Seo, Suwon-si (KR); Joon-Sung Lee, Seoul (KR)

(73) Assignee: SAMSUNG ELECTRO-MECHANICS CO., LTD.

(21) Appl. No.: 12/755,825

(22) Filed: Apr. 7, 2010

(30) Foreign Application Priority Data
Nov. 27, 2009 (KR) 10-2009-0116127

(51) Int. Cl. H05K 1/09; H05K 3/46

(52) U.S. Cl. 174/257; 156/151

(57) ABSTRACT

A printed circuit board and a manufacturing method thereof are disclosed. In accordance with an embodiment of the present invention, the printed circuit board includes a metal core having Invar layers formed on either surface of a copper layer, an insulation layer, which is formed on one surface of the metal core, and a circuit pattern, which is coupled to one surface of the insulation layer. Thus, the printed circuit board can improve thermal conductivity and deformation resistance against warpage.

### CROSS-REFERENCE TO RELATED APPLICATIONS

This application claims the benefit of Korean Patent Application No. 10-2009-0116127, filed with the Korean Intellectual Property Office on Nov. 27, 2009, the disclosure of which is incorporated herein by reference in its entirety.

### BACKGROUND

1. Technical Field

The present invention is related to a printed circuit board and a manufacturing method thereof.

2. Description of the Related Art

In step with the trends toward smaller, higher density and thinner electronic components, studies are underway to develop a thinner semiconductor package substrate with higher functionalities. Particularly, in order to implement a multi-chip package (MCP) technology, in which a plurality of semiconductor chips are stacked on one substrate, or a package on package (POP) technology, in which a plurality of substrates having chips embedded therein are stacked on one another, it is needed to develop a substrate that has a thermal expansion behavior that is similar to that of a chip and has excellent warpage properties after the chip is embedded.

With the recent trend toward higher-performance chips, the increase in operating speed of the chip causes a heating problem. Consequently, finding a solution to this problem is desperately needed. In response to this demand, a highly heat-conductive metal, for example, copper (Cu) or aluminum (Al), is commonly inserted into a core of the substrate to manufacture a metal core substrate.

Since a metal such as copper or aluminum has excellent thermal conductive properties, the metal can perform the functions of heat dissipation for the substrate. Also, a metal such as Invar has excellent thermal expansion properties for the substrate. By properly employing these metals, it is possible to inhibit the thermal expansion behavior of the substrate and perform the functions of heat dissipation.

### SUMMARY

The present invention provides a method of manufacturing a printed circuit board that can improve thermal conductivity and deformation resistance against warpage.

An aspect of the present invention provides a printed circuit board that includes a metal core having Invar layers formed on either surface of a copper layer, an insulation layer, which is formed on one surface of the metal core, and a circuit pattern, which is coupled to one surface of the insulation layer.

The printed circuit board can further include an adhesive layer, which is interposed between the metal core and the insulation layer such that adhesion of the insulation layer is improved.

The Invar layer can be formed by electroplating Invar on a surface of the copper layer. The Invar layer can be formed by rolling Invar on a surface of the copper layer. The surface of the metal core can be blackened.

The Invar layers formed on either surface of the copper layer can have different thicknesses from each other. The printed circuit board can further include a first via penetrating through the metal core. The printed circuit board can further include a second via formed on the first via. The printed circuit board can further include a bump formed on the first via.

Another aspect of the present invention provides a method of manufacturing a printed circuit board that includes forming a metal core by coupling Invar layers on either surface of a copper layer, forming an insulation layer on one surface of the metal core and forming a circuit pattern on one surface of the insulation layer.

The method can further include, between the forming of the metal core and the forming of the insulation layer, forming an adhesive layer on one surface of the metal core such that adhesion of the insulation layer is improved.

The forming of the metal core can include electroplating Invar on both surfaces of the copper layer and rolling Invar on both surfaces of the copper layer. The method can further include, before the electroplating of Invar and the forming of the insulation layer, blackening one surface of the metal core.

In the forming of the metal core, the Invar layers coupled to either surface of the copper layer can have different thicknesses from each other. The method can further include, between the forming of the metal core and the forming of the insulation layer, forming a through-hole in the metal core and, between the forming of the insulation layer and the forming of the circuit pattern, forming a via hole in accordance with where the through-hole is formed and forming a first via by way of plating in such a way that the via hole is filled.

The method can further include, after the forming of the circuit pattern, forming a second via on the first via. The method can further include, after the forming of the circuit pattern, forming a bump on the first via.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method of manufacturing a printed circuit board in accordance with an embodiment of the present invention.

FIGS. 2 to 12 illustrate a method of manufacturing a printed circuit board in accordance with an embodiment of the present invention.

### DETAILED DESCRIPTION

The features and advantages of this invention will become apparent through the below drawings and description.

A printed circuit board and a manufacturing method thereof according to a certain embodiment of the present invention will be described below in more detail with reference to the accompanying drawings. Those components that are the same or are in correspondence are rendered the same reference numeral regardless of the figure number, and redundant descriptions are omitted.

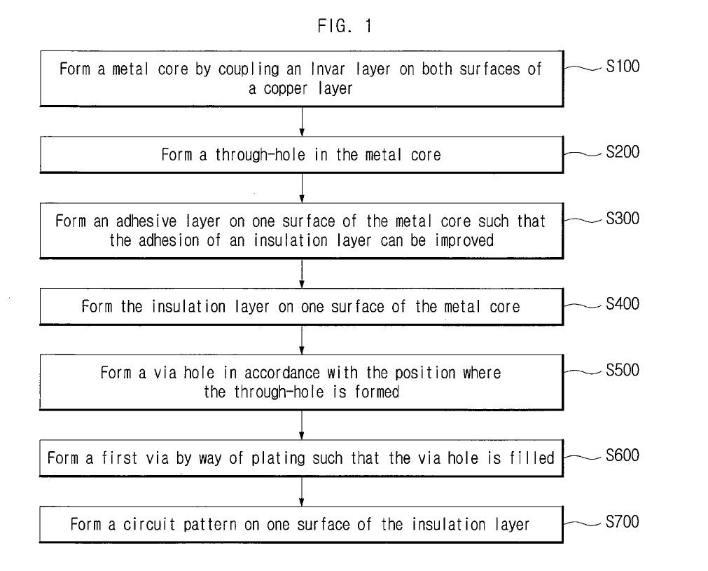

FIG. 1 is a flowchart illustrating a method of manufacturing a printed circuit board 1000 in accordance with an embodiment of the present invention. As illustrated in FIG. 1, the method of manufacturing the printed circuit board 1000 in accordance with an embodiment of the present invention includes forming a metal core 100 by coupling Invar layers 120 and 122 to either surface of a copper layer 110 (S100), forming a through-hole 300 in the metal core 100 (S200), forming an adhesive layer 220 on one surface of the metal core 100 such that the adhesion of an insulation layer 230 becomes improved (S300), forming the insulation layer 230 on one surface of the metal core 100 (S400), forming a via hole 310 in accordance with the position where the through-hole 300 is formed (S500), forming a first via 320 by way of plating such that the via hole 310 is filled (S600) and forming a circuit pattern 242 on one surface of the insulation layer 230 (S700). Accordingly, the thermal conductivity of the printed circuit board 1000 and deformation resistance against warpage can be improved at the same time.

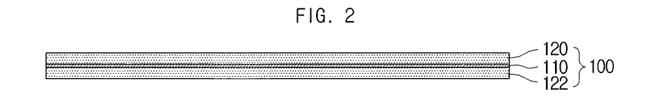

FIGS. 2 to 12 illustrate the method of manufacturing the printed circuit board 1000 in accordance with an embodiment of the present invention. As illustrated in FIG. 2, the Invar layers 120 and 122 can be coupled to either surface of the copper layer 110 to form the metal core 100 (S100).

Since copper has high thermal conductivity and Invar has low thermal expansion coefficients, the metal core 100 including the copper layer 110 and the Invar layers 120 and 122 has high thermal conductivity and excellent deformation resistance against warpage.

The metal core 100 can be manufactured by rolling Invar on both surfaces of the copper layer 110 to form the Invar layers 120 and 122.

In another example, the metal core 100 can be manufactured by electroplating Invar on both surfaces of the copper layer 110 to form the Invar layers 120 and 122. Here, used for the copper layer 110 can be, for example, a copper foil of between 12 micrometers and 35 micrometers inclusive, and Invar can be electroplated by using a roll-to-roll method. The thicknesses of the Invar layers 120 and 122 can be between 3 micrometers and 30 micrometers inclusive.

The thicknesses of the Invar layers 120 and 122, which are respectively formed on the upper and lower surfaces of the copper layer 110, can be different from each other. By forming the Invar layers 120 and 122 having different thicknesses on the upper and lower surfaces of the copper layer 110, the warpage can be controlled if the printed circuit board 1000 is employed in a package, for example, POP (package on package), having a vertically asymmetrical structure.

Since the metal core 100 has the Invar layers 120 and 122 formed on either surface of the copper layer 110, the cross-section of the metal core 100 can have a structure in which the Invar layers 120 and 122 support the upper and lower surfaces of the copper layer 110. This kind of structure is the same as the structure of H-beams used in building structures and can improve the stiffness of the metal core 100.

Meanwhile, if the Invar layers 120 and 122 are formed by way of electroplating, the surface of the metal core 100 can be blackened by improving the surface roughness of the metal core 100 in order to increase the adhesion between the Invar layers 120 and 122 and the insulation layer 230.

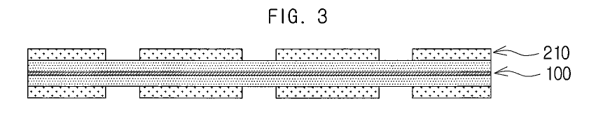

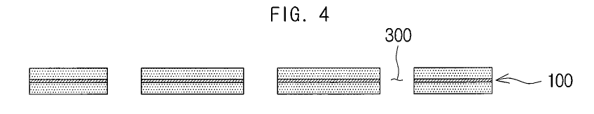

Next, as illustrated in FIGS. 3 and 4, the through-hole 300 can be formed in the metal core 100 (S200). The through-hole 300 can be chemically formed by first adhering a dry film 210 on the surface of the metal core 100 and then exposing and developing the dry film 210 to be peeled.

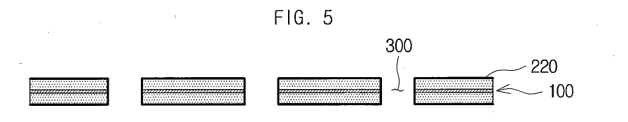

Next, as illustrated in FIG. 5, the adhesive layer 220 can be formed on one surface of the metal core 100 such that the adhesion of the insulation layer 230 can be improved (S300). The adhesive layer 220 can be formed not only on the surface of the metal core 100 but also on an inner circumferential surface of the through-hole 300.

The adhesive layer 220 can be a dielectric material, for example, liquid-state polyimide or liquid-state synthetic resin. Such liquid-state material can be coated on the surface of the metal core 100 and then dried using hot wind to form the adhesive layer 220.

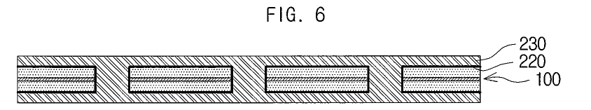

Next, as illustrated in FIG. 6, the insulation layer 230 can be formed on one surface of the metal core 100 (S400). The insulation layer 230 can cover both surfaces of the metal core 100 and fill the through-hole 300. The coupling strength of the insulation layer 230 with the adhesive layer 220 can be further improved by stacking prepreg on the metal core 100 and then baking the prepreg.

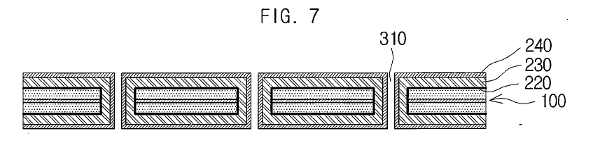

Next, as illustrated in FIG. 7, the via hole 310 can be formed in the metal core 100 (S500). The via hole 310 can be formed in accordance with the position where the through-hole 300 is formed. The via hole 310 can be formed by using a carbon dioxide laser or by way of mechanical drilling.

Next, as illustrated in FIG. 7, a conductive layer 240 can be formed on the surface of the metal core 100 after forming the via hole 310. The conductive layer 240 can be, for example, a copper plated layer and formed on both surfaces of the insulation layer 230 and the inner circumferential surface of the through-hole 300.

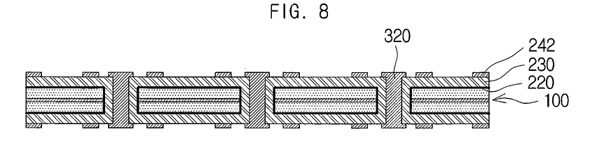

Next, as illustrated in FIG. 8, the first via 320 can be formed by way of plating such that the circuit pattern 242 and the via hole 310 are filled (S600 and S700). The circuit pattern 242 can be formed by patterning the conductive layer 240 or can be formed through an additive method or a subtractive method.

Then, the first via 320 can be formed by way of plating in such a way that the through-hole 300 is filled. Since the first via 320 is formed vertically in the metal core 100, the first via 320 not only provides electrical connection between an upper side and a lower side of the metal core 100 but also releases the heat inside the metal core 100 to the outside.

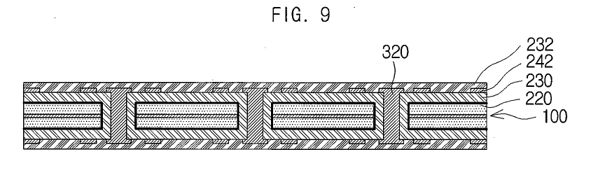

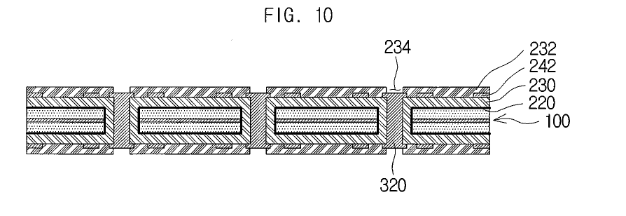

Next, as illustrated in FIGS. 9 and 10, an insulation layer 232 can be formed on both surfaces of the metal core 100, and an opening 234 can be formed in accordance with the position where the first via 320 is formed.

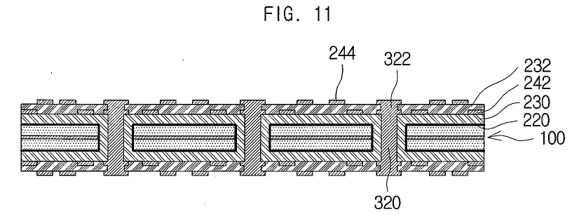

Next, as illustrated in FIG. 11, a circuit pattern 244 can be formed on the surface of the insulation layer 232, and a second via 322, which is coupled to the first via 320 and fills the opening 234, can be formed. The second via 322 can be in the form of a stack via that is stacked on the first via 320.

Since the second via 322 is formed on the first via 320, the second via 322 not only provides electrical connection but also functions as a thermal conductor releasing the heat inside the metal core 100 to the outside.

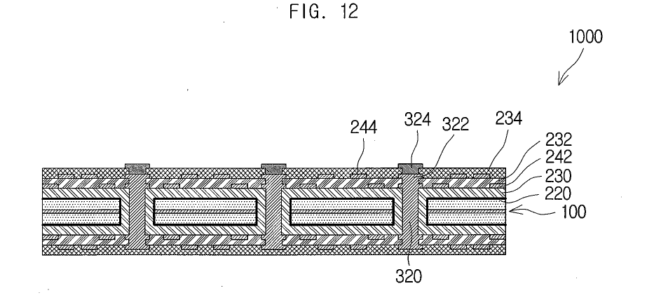

Next, as illustrated in FIG. 12, a solder resist layer 234 can be formed on the circuit pattern 242, and a bump 324 can be formed in accordance with the position where the second via 322 is formed.

Since the bump 324 is coupled to the second via 322, the bump 324 not only provides electrical connection with the outside of the printed circuit board 1000 but also releases the heat inside the metal core 100 to the outside.

While the spirit of the present invention has been described in detail with reference to a particular embodiment, the embodiment is for illustrative purposes only and shall not limit the present invention. It is to be appreciated that those skilled in the art can change or modify the embodiments without departing from the scope and spirit of the present invention.

What is claimed is:

1. A printed circuit board comprising:
a metal core having Invar layers formed on either surface of a copper layer;
an insulation layer formed on one surface of the metal core; and
a circuit pattern coupled to one surface of the insulation layer.

2. The printed circuit board of claim 1, further comprising an adhesive layer interposed between the metal core and the insulation layer such that adhesion of the insulation layer is improved.

3. The printed circuit board of claim 1, wherein the Invar layer is formed by electroplating Invar on a surface of the copper layer.

4. The printed circuit board of claim 1, wherein the Invar layer is formed by rolling Invar on a surface of the copper layer.

5. The printed circuit board of claim 3, wherein a surface of the metal core is blackened.

6. The printed circuit board of claim 1, wherein the Invar layers formed on either surface of the copper layer have different thicknesses from each other.

7. The printed circuit board of claim 1, further comprising a first via penetrating through the metal core.

8. The printed circuit board of claim 7, further comprising a second via formed on the first via.

9. The printed circuit board of claim 7, further comprising a bump formed on the first via.

10. A method of manufacturing a printed circuit board, the method comprising:
forming a metal core by coupling Invar layers on either surface of a copper layer;
forming an insulation layer on one surface of the metal core; and
forming a circuit pattern on one surface of the insulation layer.

11. The method of claim 10, further comprising, between the forming of the metal core and the forming of the insulation layer, forming an adhesive layer on one surface of the metal core such that adhesion of the insulation layer is improved.

12. The method of claim 10, wherein the forming of the metal core comprises rolling Invar on both surfaces of the copper layer.

13. The method of claim 10, wherein the forming of the metal core comprises electroplating Invar on both surfaces of the copper layer.

14. The method of claim 13, further comprising, before the electroplating of Invar and the forming of the insulation layer, blackening one surface of the metal core.

15. The method of claim 10, wherein, in the forming of the metal core, the Invar layers coupled to either surface of the copper layer have different thicknesses from each other.

16. The method of claim 10, further comprising, between the forming of the metal core and the forming of the insulation layer:
forming a through-hole in the metal core; and
between the forming of the insulation layer and the forming of the circuit pattern,
forming a via hole in accordance with where the through-hole is formed; and
forming a first via by way of plating in such a way that the via hole is filled.

17. The method of claim 16, further comprising, after the forming of the circuit pattern, forming a second via on the first via.

18. The method of claim 16, further comprising, after the forming of the circuit pattern, forming a bump on the first via.
